(19) United States
(12) Patent Application Publication
(10) Pub. No.: US 2026/0324410 A1
(43) Pub. Date: Oct. 15, 2026

(54) SEMICONDUCTOR DEVICE WITH COVERING INSULATION LINER AND METHOD FOR FABRICATING THE SAME

(71) Applicant: NANYA TECHNOLOGY CORPORATION, NEW TAIPEI CITY (TW)

(72) Inventor: YING-CHENG CHUANG, NEW TAIPEI CITY (TW)

(21) Appl. No.: 19/175,178

(22) Filed: Apr. 10, 2025

(51) Int. Cl. H01L 23/532; H01L 21/768; H01L 23/528

(52) U.S. Cl. CPC H10W 20/47; H10W 20/075; H10W 20/076; H10W 20/089; H10W 20/435

(57) ABSTRACT

The present application discloses a semiconductor device and a method for fabricating the semiconductor device. The semiconductor device includes a substrate including an array area and a peripheral area adjacent to the array area; a first trench inwardly positioned in the array area; a basin inwardly positioned in the peripheral area; a filling insulation layer completely filling the first trench and covering a top surface of the substrate within the array area; a top insulation layer positioned on the filling insulation layer and within the array area; and a covering insulation liner conformally and completely covering the top insulation layer and an inner surface of the basin. The covering insulation liner and the top insulation layer contact each other directly.

### TECHNICAL FIELD

The present disclosure relates to a semiconductor device and a method for fabricating the semiconductor device, and more particularly, to a semiconductor device with a covering insulation liner and a method for fabricating the semiconductor device with the covering insulation liner.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate including an array area and a peripheral area adjacent to the array area; a first trench inwardly positioned in the array area; a basin inwardly positioned in the peripheral area; a filling insulation layer completely filling the first trench and covering a top surface of the substrate within the array area; a top insulation layer positioned on the filling insulation layer and within the array area; and a covering insulation liner conformally and completely covering the top insulation layer and an inner surface of the basin. The covering insulation liner and the top insulation layer contact each other directly.

Another aspect of the present disclosure provides a semiconductor device including a substrate including an array area and a peripheral area adjacent to the array area; a filling insulation layer including a first plug portion positioned in the array area of the substrate, and a flat portion positioned on the first plug portion and covering a top surface of the substrate within the array area; a top insulation layer positioned on the flat portion of the filling insulation layer and within the array area; a peripheral filling layer positioned in the peripheral area of the substrate and adjacent to the array area of the substrate; and a covering insulation liner including an array portion conformally covering the top insulation layer, and a peripheral portion connecting to the array portion and positioned between the peripheral filling layer and the substrate.

Another aspect of the present disclosure provides a method for fabricating a semiconductor device including providing a substrate including an array area and a peripheral area adjacent to the array area, and forming a plurality of first trenches in the array area; forming a layer of first insulating material filling the plurality of first trenches and covering the array area and the peripheral area, and forming a top insulation layer covering the layer of first insulating material; removing the top insulation layer within the peripheral area, the first insulating material within the peripheral area, and a portion of the substrate within the peripheral area to turn the layer of first insulating material into a filling insulation layer in the array area and form a basin in the peripheral area; conformally forming a peripheral insulation layer on the top insulation layer and within the basin; forming an under layer to completely fill the basin; removing the peripheral insulation layer within the array area to expose the top insulation layer; removing the under layer to expose the peripheral insulation layer within the peripheral area; and conformally forming a covering insulation liner covering the top insulation layer and the peripheral insulation layer.

Due to the design of the semiconductor device of the present disclosure, the covering insulation liner, which is in direct contact with the top insulation layer and extends to the basin of the peripheral area, may provide structural reinforcement to the trenches, preventing profile deformation (particularly at the edges of the array area) during subsequent semiconductor processing steps. As a result, the defect of the semiconductor device may be reduced, and the in-line overlay, electrical characteristics, and yield of the semiconductor device may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure; and

FIGS. 2 to 20 illustrate, in schematic cross-sectional view diagrams, a flow for fabricating the semiconductor device in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

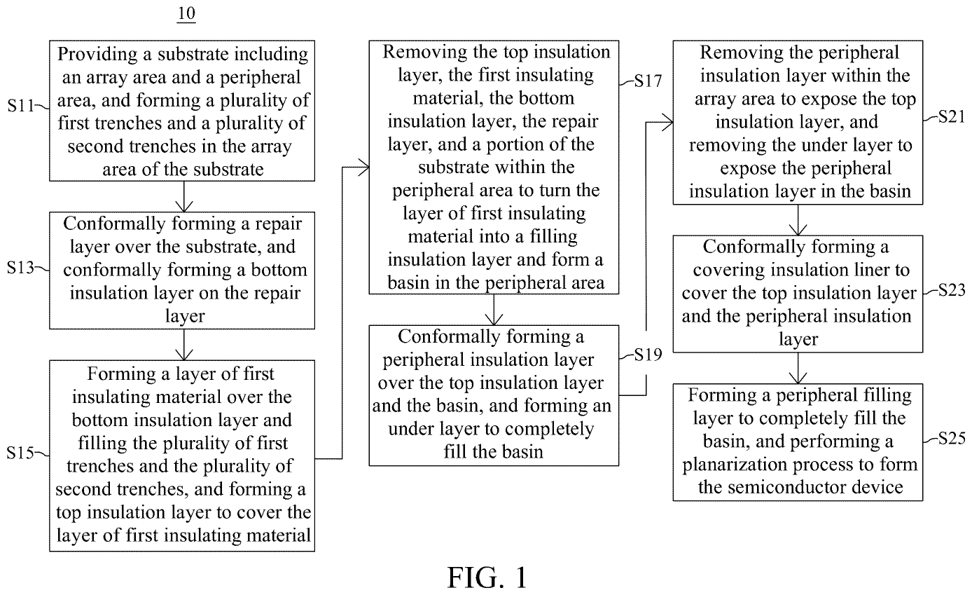

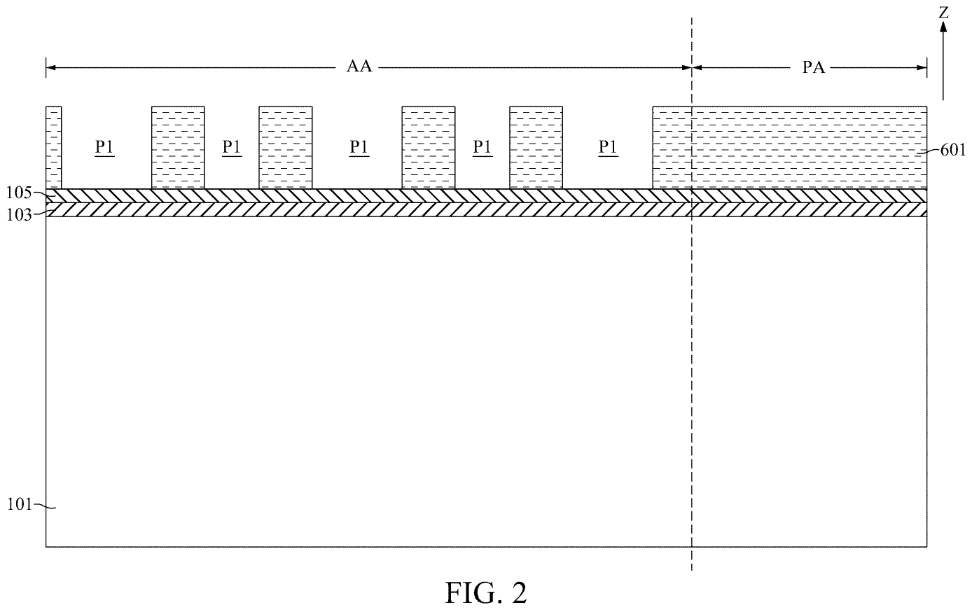

FIG. 1 illustrates, in a flowchart diagram form, a method 10 for fabricating a semiconductor device 1A in accordance with one embodiment of the present disclosure. FIGS. 2 to 20 illustrate, in schematic cross-sectional view diagrams, a flow for fabricating the semiconductor device 1A in accordance with one embodiment of the present disclosure.

With reference to FIGS. 1 to 4, at step S11, a substrate 101 including an array area AA and a peripheral area PA may be provided, and a plurality of first trenches TR1 and a plurality of second trenches TR2 may be formed in the array area AA of the substrate 101.

With reference to FIG. 2, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

In some embodiments, the substrate 101 may include an array area AA and a peripheral area PA. The peripheral area PA may be adjacent to the array area AA in a cross-sectional perspective. The peripheral area PA may surround the array area AA in a top-view perspective (not shown).

In some embodiments, the substrate 101 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and 200 nm.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

With reference to FIG. 2, a bottom hard mask layer 103 may be formed on the substrate 101. In some embodiments, the bottom hard mask layer 103 may be formed of, for example, silicon oxide. In some embodiments, the bottom hard mask layer 103 may be formed by performing a rapid thermal oxidation to the substrate 101 in an oxide/oxynitride atmosphere. In some embodiments, the temperature of the rapid thermal oxidation may be about 1000 °C.

With reference to FIG. 2, a top hard mask layer 105 may be formed on the bottom hard mask layer 103. In some embodiments, the top hard mask layer 105 may be formed of, for example, silicon oxide. In some embodiments, the top hard mask layer 105 may be formed by, for example, chemical vapor deposition, plasma enhanced chemical vapor deposition. For example, the top hard mask layer 105 may be deposited by chemical vapor deposition using a silicate or silicon source, a number of doping sources, and an ozone source. In some embodiments, the doping sources may be optional. In some embodiments, the doping sources may be, for example, triethylborate, triethylphosphate, triethyphosphite, trimethylphosphate, or trimethylphosphite. In some embodiments, the silicate or silicon source may be, for example, tetramethylorthosilicate. The doping sources may result in impurity atoms such as phosphorus or boron in the top hard mask layer 105.

With reference to FIG. 2, a first mask layer 601 may be formed on the top hard mask layer 105. In some embodiments, the first mask layer 601 may be a photoresist layer and may include a trench pattern P1 of the plurality of first trenches TR1 and the plurality of second trenches TR2.

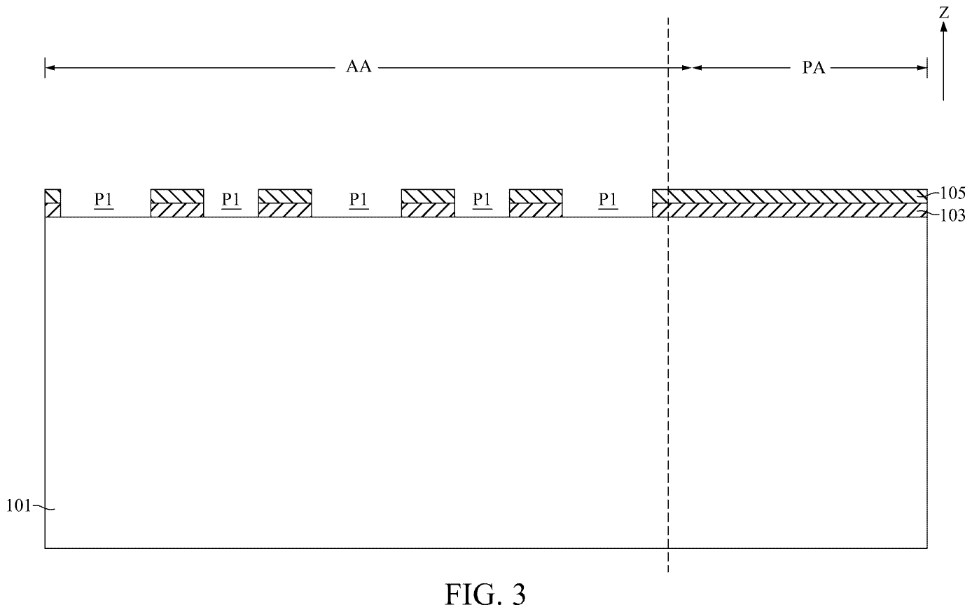

With reference to FIG. 3, a hard mask etching process may be performed using the first mask layer 601 as the mask to remove a portion of the top hard mask layer 105 and a portion of the bottom hard mask layer 103. After the hard mask etching process, the trench pattern P1 of the first mask layer 601 may be transferred to the top hard mask layer 105 and the bottom hard mask layer 103. The first mask layer 601 may be removed after the formation of the trench pattern P1. In some embodiments, the removal of the first mask layer 601 may be, for example, an ashing process or other applicable semiconductor processes.

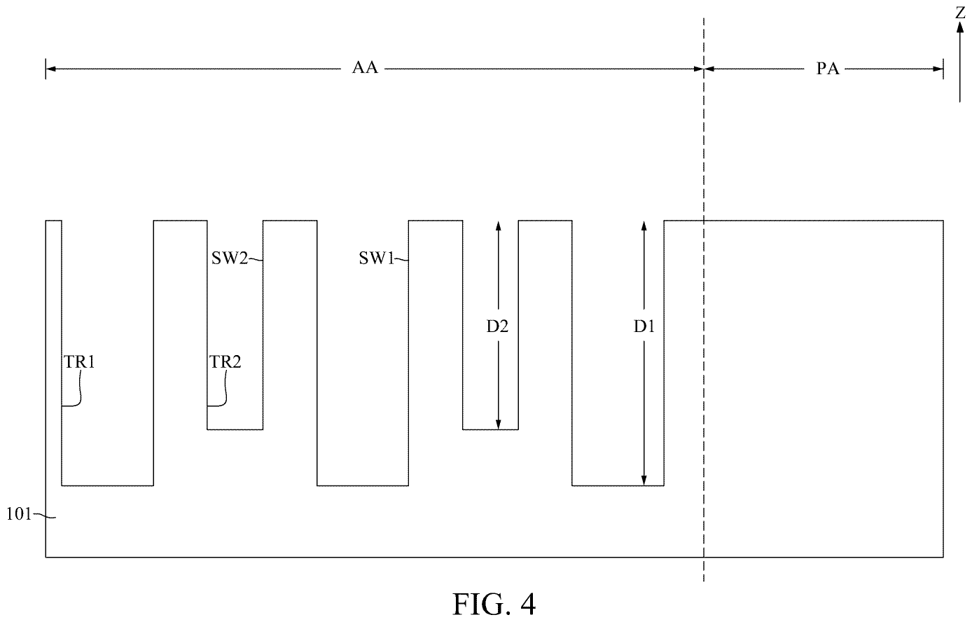

With reference to FIG. 4, a trench etching process may be performed, utilizing the bottom hard mask layer 103 and the top hard mask layer 105 as masks, to remove a portion of the substrate 101. This process results in the formation of the plurality of first trenches TR1 and the plurality of second trenches TR2 in the array area AA of the substrate 101. In some embodiments, the sidewall SW1 of the first trench TR1 may be substantially vertical. In some embodiments, the sidewall SW2 of the second trench TR2 may be substantially vertical. In some embodiments, the aspect ratio of the first trench TR1 may be between about 4:1 and about 17:1, about 8:1 and about 16:1, or about 9.5:1 and about 15:1. In some embodiments, the aspect ratio of the second trench TR2 may be between about 4:1 and about 17:1, about 8:1 and about 16:1, or about 9.5:1 and about 15:1. In some embodiments, the width of the first trench TR1 may be greater than the width of the second trench TR2. In some embodiments, the depth D1 of the first trench TR1 may be greater than the depth D2 of the second trench TR2.

It should be noted that, in the description of the present disclosure, a surface is “substantially vertical” if there exists a vertical plane from which the surface does not deviate by more than three times the root mean square roughness of the surface.

In some embodiments, a post-etching cleaning process may be performed after the formation of the plurality of first trenches TR1 and the plurality of second trenches TR2. The post-etching cleaning process may include three stages with inter-stage rinses between stages. Detailedly, during the first stage of the post-etching cleaning process, a first cleaning solution may be applied to the intermediate semiconductor device after the formation of the plurality of first trenches TR1 and the plurality of second trenches TR2. The first cleaning solution may be rinsed by the first inter-stage rinse. During the second stage of the post-etching cleaning process, a second cleaning solution may be applied to the intermediate semiconductor device and the second cleaning solution may be subsequently rinsed by a second inter-stage rinse. During the third stage of the cleaning process, a third cleaning solution may be applied to the intermediate semiconductor device and then be rinsed by a post-stage rinse.

In some embodiments, during the first stage of the post-etching cleaning process, the intermediate semiconductor device may be spun at a rate between about 10 rpm and about 2000 rpm or between about 100 rpm and 1000 rpm. The first cleaning solution may be sprayed onto the intermediate semiconductor device to cover the entire front side of the intermediate semiconductor device. Simultaneously to applying the first cleaning solution onto the front side of the intermediate semiconductor device, water or other suitable solution may be applied to the backside of the intermediate semiconductor device to clean the backside of the intermediate semiconductor device.

In some embodiments, the first cleaning solution may include diluted hydrofluoric acid. The concentration of the first cleaning solution may be between about 5 parts deionized water to one part hydrofluoric acid and about 1000 parts deionized water to one part hydrofluoric acid, about 300 parts deionized water to one part hydrofluoric acid, or about 50 parts deionized water to one part hydrofluoric acid. Generally, the front side of the intermediate semiconductor device may be exposed to the first cleaning solution for a time sufficient to etch either a sacrificial oxide (typically around 50 angstroms to 200 angstroms) or a native oxide (typically around 10 angstroms.) In some embodiments, the process time of the first stage of the cleaning process may be between about 20 seconds and about 50 seconds, about 40 seconds, or about 30 seconds. In some embodiments, the process time of the first stage of the post-etching cleaning process may be between about 1 minutes and about 5 minutes.

In some embodiments, the first cleaning solution may further include fluoride compound(s), organic acid salt(s), and/or glyoxylic acid.

The fluorine compound(s) may be contained in the first cleaning solution as a component for removing the etching residue of the trench etching process. Examples of the fluorine compound(s) may include hydrofluoric acid and ammonium or amine fluoride salts such as, for example, ammonium fluoride, ammonium hydrogen fluoride, methylamine hydrofluoride, ethylamine hydrofluoride, propylamine hydrofluoride, tetramethylammonium fluoride, tetraethylammonium fluoride, ethanolamine hydrofluoride, methylethanolamine hydrofluoride, dimethylethanolamine hydrofluoride, and triethylenediamine hydrofluoride. In some embodiments, the concentration of the fluorine compound(s) in the first cleaning solution may be determined according to the composition of the etching residue. For example, the concentration of the fluorine compound(s) may be between about 0.1 mass % and about 5 mass % of the entire composition of the first cleaning solution, or between about 0.2 mass % and about 3 mass % of the entire composition of the first cleaning solution.

The organic acid salt(s) may include, for example, ammonium oxalate, ammonium tartrate, ammonium citrate, and ammonium acetate. The organic acid salt(s) may act as a pH adjusting agent(s) or buffer agent(s) in the first cleaning solution. The concentration of the organic acid salt(s) may be between about 0.1 mass % and about 10 mass % of the entire composition of the first cleaning solution, or between about 0.3 mass % and about 5 mass % of the entire composition of the first cleaning solution.

The glyoxylic contained in the first cleaning solution may serve as a corrosion inhibitor.

In some embodiments, the first cleaning solution may further include a resist removal component. Examples of the resist removal component include tetramethylammonium hydroxide and/or monomethanolamine.

The first inter-stage rinse may be performed after the first stage of the post-etching cleaning process. During the first inter-stage rinse, the intermediate semiconductor device after the first stage of the post-etching cleaning process may be rotated at between about 10 rpm and about 1000 rpm while being rinsed with deionized water. In some embodiments, the rinse temperature may be between about 19 °C and about 23 °C. In some embodiments, the process time of the first inter-stage rinse may be between about 20 seconds and about 50 seconds, or about 30 seconds.

In some embodiments, the deionized water used for the first inter-stage rinse may be oxygenated or ozonated by dissolving oxygen gas or ozone gas before rinsing the intermediate semiconductor device. Dissolved oxygen or ozone may be added to the deionized water in a concentration of greater than 1 ppm to serve as an oxidant. For example, the concentration of dissolved oxygen or ozone may be between about 1 ppm and about 200 ppm or between about 2 ppm and about 20 ppm. For another example, the deionized water may be saturated with dissolved oxygen or ozone. Alternatively, hydrogen peroxide may be added to the deionized water in a concentration of greater than 100 ppm to serve as an oxidant. Whichever oxidant is used, it should have an oxidation potential sufficient to oxidize the most noble metal in the solution. Copper (Cu²⁺), with a standard reduction potential of 0.3V, is usually the most noble metal present. Therefore, a standard reduction potential of greater than 0.5V is desired. Oxygen or ozone will solvate the metal ions and prevent precipitation by oxidizing the metal ions that are in solution. This will help decrease the processing time by making the first inter-stage rinse more effective.

In some embodiments, the deionized water used for the first inter-stage rinse may be carbon dioxide dissolved into it to dissipate static electricity that builds up in the deionized water. Static electricity builds up in the deionized water may originate from the rotation of the intermediate semiconductor device. The dissolved carbon dioxide may also make the deionized water more acidic and therefore reduces any metallic contamination. In some embodiments, carbon dioxide may be dissolved into the deionized water in an amount sufficient to dissipate static electricity. For example, the amount of carbon dioxide dissolved into the deionized water may be sufficient to decrease the resistivity of the deionized water to less than 5 Megaohm·cm.

In some embodiments, the deionized water used for the first inter-stage rinse may have isopropyl alcohol, or any other liquid with a surface tension lower than that of the deionized water, added to it. Isopropyl alcohol may aid by making the deionized water spread out over the front side of the intermediate semiconductor device so that the chemicals are removed more quickly. Isopropyl alcohol may also help the rinse spin off of the intermediate semiconductor device during spinning. Alternatively, isopropyl alcohol vapor may be blown onto the front side of the intermediate semiconductor device while rinsing to assist the first inter-stage rinse.

In some embodiments, during the second stage of the post-etching cleaning process, the intermediate semiconductor device after the first inter-stage rinse may be spun at a rate between about 10 rpm and about 2000 rpm or between about 100 rpm and 1000 rpm. The second cleaning solution may be sprayed onto the intermediate semiconductor device to cover the entire front side of the intermediate semiconductor device. Simultaneously to applying the second cleaning solution onto the front side of the intermediate semiconductor device, water or other suitable solution may be applied to the backside of the intermediate semiconductor device to clean the backside of the intermediate semiconductor device.

In some embodiments, the second cleaning solution may be an alkaline solution including, for example, aqueous solutions of inorganic compounds such as sodium hydroxide, potassium hydroxide and ammonium hydroxide, and aqueous solution of organic compounds such as tetramethylammonium hydroxide and choline. The second cleaning solution may also include hydrogen peroxide. The purpose of the ammonium hydroxide and the hydrogen peroxide in the second cleaning solution is to remove particles and residual organic contaminants from the front side of the intermediate semiconductor device.

For example, in the present embodiment, the second cleaning solution may include ammonium hydroxide, hydrogen peroxide, and water. The ammonium hydroxide, hydrogen peroxide, and water may be present in concentrations defined by dilution ratios of between 5/1/1 to 1000/1/1, respectively. In some embodiments, the ammonium hydroxide/hydrogen peroxide ratio may vary between 0.05/1 and 5/1. In some embodiments, no hydrogen peroxide is used at all. The ammonium hydroxide in the second cleaning solution would be from a solution of 28-29% w/w of ammonia to water. The hydrogen peroxide in the second cleaning solution would be from a solution of 31-32% w/w of hydrogen peroxide to water. The pH of the second cleaning solution may be between about 9 and 12 or between about 10 and 11 due to the ammonium hydroxide and the hydrogen peroxide.

In some embodiments, the second cleaning solution may further include dissolved hydrogen gas. The dissolved hydrogen gas in the second cleaning solution may provide cavitation (bubble creation) to the second cleaning solution. Providing cavitation to the second cleaning solution may enhance the post-etching cleaning process. In some embodiments, the concentration of the dissolved hydrogen gas may be between about 0.01 mg/L and about 5 mg/L or between about 0.1 mg/L and about 5 mg/L. In some embodiments, other suitable cavitation gases such as nitrogen, helium, Argon, or oxygen may also be used. For example, dissolved oxygen having concentration between about 1 mg/L and about 20 mg/L may be used in the second cleaning solution.

In some embodiments, the process time of the second stage of the post-etching cleaning process may be between about 30 seconds and about 100 seconds, between about 30 seconds and 90 seconds, or between about 30 seconds and about 60 seconds. In some embodiments, the temperature of the second cleaning solution may be between about 40 °C and about 85 °C.

The second inter-stage rinse may be performed after the second stage of the post-etching cleaning process. The second inter-stage rinse may be performed with a procedure similar to the first inter-stage rinse, and descriptions thereof are not repeated herein.

In some embodiments, during the third stage of the post-etching cleaning process, the intermediate semiconductor device after the second inter-stage rinse may be spun at a rate between about 10 rpm and about 2000 rpm or between about 100 rpm and 1000 rpm. The third cleaning solution may be sprayed onto the intermediate semiconductor device to cover the entire front side of the intermediate semiconductor device. Simultaneously to applying the third cleaning solution onto the front side of the intermediate semiconductor device, water or other suitable solution may be applied to the backside of the intermediate semiconductor device to clean the backside of the intermediate semiconductor device.

In some embodiments, the third cleaning solution may be an acidic solution including, for example, aqueous solution of inorganic acids such as hydrochloric acid, hydrofluoric acid, sulfuric acid and nitric acid, and aqueous solution of organic acids such as oxalic acid, citric acid, malonic acid, malic acid, fumaric acid and maleic acid. In some embodiments, the third cleaning solution may also include hydrogen peroxide. The concentration of the acidic solution may be between about 0.001% and about 10% by weight or between about 0.01% and about 5% by weight. When the concentration is too low, the washing effect may not be obtained sufficiently. When the concentration is too high, metal-corrosion of the washing apparatus or the other related apparatus may occur.

A post-stage rinse may be performed after the third stage of the post-etching cleaning process. The post-stage rinse may be performed with a procedure similar to the first inter-stage rinse, and descriptions thereof are not repeated herein.

In some embodiments, the second stage and the third stage of the post-etching cleaning process may be optional. In other words, only the first stage of the post-etching cleaning process may be performed. In some embodiments, the third stage of the post-etching cleaning process may be optional. In other words, only the first stage and the second stage of the post-etching cleaning process may be performed.

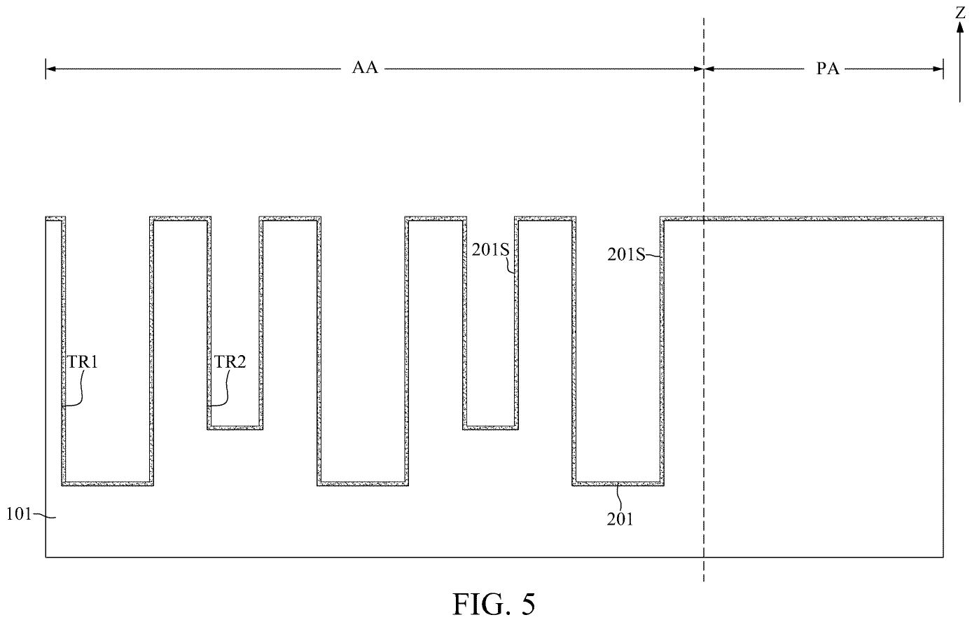

With reference to FIG. 5, the top hard mask layer 105 and the bottom hard mask layer 103 may be removed by, for example, an etching process such as a wet etching process or a dry etching process. In the present embodiment, the top hard mask layer 105 and the bottom hard mask layer 103 may be removed by wet etching process. In some embodiments, the etch rate ratio of the top hard mask layer 105 (or the bottom hard mask layer 103) to the substrate 101 may be between about 100:1 and about 1.05:1, between about 15:1 and about 2:1, or between about 10:1 and about 2:1 during the etching process.

With reference to FIG. 1 and FIGS. 5 to 7, at step S13, a repair layer 201 may be conformally formed over the substrate 101, and a bottom insulation layer 210 may be conformally formed on the repair layer 201.

With reference to FIG. 5, a repairing layer 201 may be conformally formed on the substrate 101, within (or on) the plurality of first trenches TR1, and within (or on) the plurality of second trenches TR2. The top surface 101TS of the substrate 101 and the inner surfaces of the plurality of first trenches TR1 and the plurality of second trenches TR2 may be conformally covered by the repair layer 201. The part of the repair layer 201 disposed within the first trenches TR1 and the second trenches TR2 may respectively include a U-shaped cross-sectional profile. In some embodiments, the sidewall 201S of the repair layer 201 may be substantially vertical.

In some embodiments, the repairing layer 201 may be formed of, for example, silicon. In some embodiments, the repairing layer 201 may be formed by, for example, atomic layer deposition, chemical vapor deposition, or other applicable deposition processes. In some embodiments, the repairing layer 201 may fill seams of the plurality of first trenches TR1 and the plurality of second trenches TR2. In some embodiments, the repairing layer 201 may serve as a buffer or a stress-reducing layer. The repairing layer 201 may be used to mitigate the mechanical stresses caused by the difference in thermal expansion coefficients between the substrate 101 and the insulating material which will be filled in later.

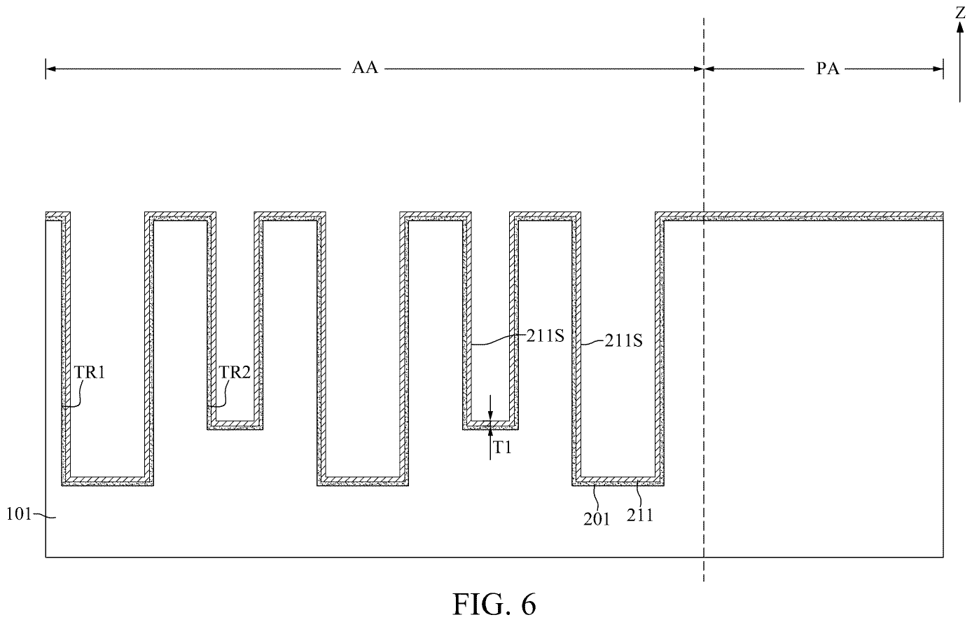

With reference to FIG. 6, a lower portion 211 of the bottom insulation layer 210 may be conformally formed on the repair layer 201. The part of the lower portion 211 disposed within the first trenches TR1 and the second trenches TR2 may include a U-shaped cross-sectional profile. In some embodiments, the sidewall 211S of the lower portion 211 may be substantially vertical. In some embodiments, the thickness T1 of the lower portion 211 of the bottom insulation layer 210 may be about 1 nm.

In some embodiments, the lower portion 211 may be formed of silicon oxide. In some embodiments, the atomic composition of the lower portion 211 may only include silicon and oxygen. In some embodiments, the lower portion 211 may be formed by, for example, a chemical vapor deposition. The precursor for forming the lower portion 211 may only include oxygen gas. The process temperature for forming lower portion 211 of the bottom insulation layer 210 may be lower than 500 °C. This low-temperature reaction, combined with a single-gas environment, helps prevent side reactions, in a high temperature environment (e.g., greater than 500 °C), between the substrate 101 and the precursors (e.g., hydrogen gas and/or chlorine), which could otherwise lead to a distorted trench profile and negatively impact the electrical characteristics of the semiconductor device 1A.

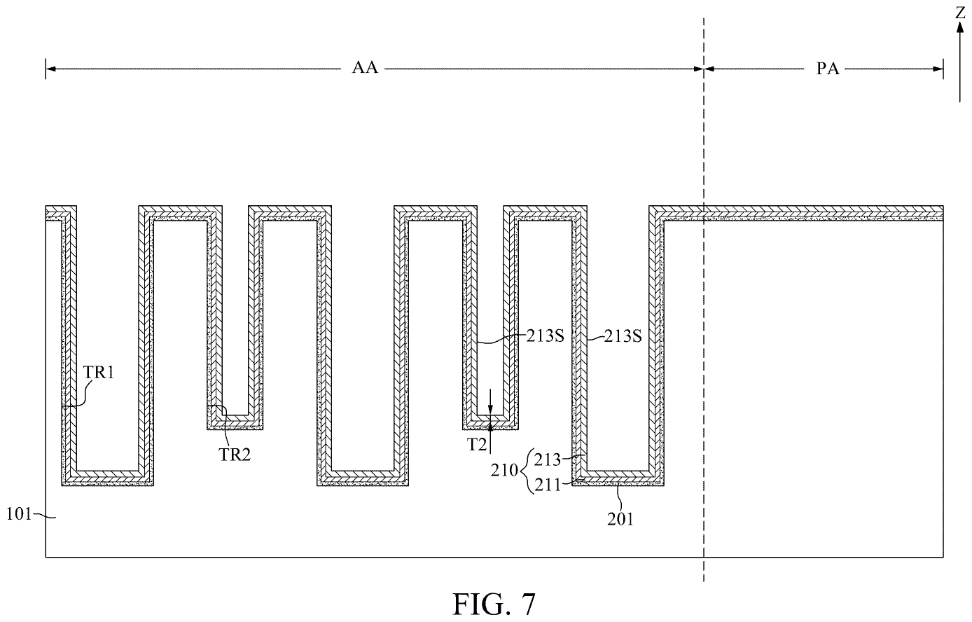

With reference to FIG. 7, an upper portion 213 of the bottom insulation layer 210 may be conformally formed on the lower portion 211 of the bottom insulation layer 210. The part of the upper portion 213 disposed within the first trenches TR1 and the second trenches TR2 may include a U-shaped cross-sectional profile. In some embodiments, the sidewall 213S of the upper portion 305 may be substantially vertical. In some embodiments, the thickness T2 of the upper portion 213 of the bottom insulation layer 210 may be between about 5 nm and about 15 nm.

In some embodiments, the upper portion 213 may be formed of silicon oxide. In some embodiments, the atomic composition of upper portion 213 may only include silicon, oxygen, chlorine, and hydrogen. In some embodiments, the chlorine concentration of the upper portion 213 may be greater than the chlorine concentration of the lower portion 211. In some embodiments, the hydrogen concentration of the upper portion 213 may be greater than the hydrogen concentration of the lower portion 211.

In some embodiments, the upper portion 213 may be formed by, for example, an atomic layer deposition. The precursor for forming the upper portion 213 may include hexachlorodisilane (HCDS), hydrogen gas, and oxygen gas. The process temperature for forming the upper portion 213 of the bottom insulation layer 210 may be greater than or equal to 500 °C. Due to the presence of the lower portion 211, the hydrogen gas (and/or out gas such as chlorine) in the precursor used for atomic layer deposition does not react with the substrate 101, ensuring that the profiles of the first trenches TR1 and the second trenches TR2 remain intact.

Detailedly, the precursor for forming the upper portion 213 using atomic layer deposition may include HCDS as the silicon source, oxygen gas as the oxygen source, and hydrogen gas. In some embodiments, Lewis base catalysts like pyridine or trimethylamine may be incorporated to enhance deposition efficiency. The deposition process may involve alternating exposure of the intermediate semiconductor device illustrated in FIG. 6 to precursors, with intermediate purging or pumping to remove residual gases and by-products. The HCDS reacts with hydroxyl groups (—OH) on the substrate surface, forming silicon-chlorine complexes (e.g., —Si₂Cl₄ or —Si₂Cl₅), which are subsequently converted to silicon oxide by reacting with oxygen gas and hydrogen gas. This cycle is repeated to achieve the desired layer thickness (e.g., thickness T2).

In some embodiments, the deposition of the lower portion 211 and the deposition of the upper portion 213 may be performed at the same process chamber which can reduce the manufacture time while ensuring trench profile integrity.

With reference to FIGS. 1, 8, and 9, at step S15, a layer of first insulating material 501 may be formed over the bottom insulation layer 210 and filling the plurality of first trenches TR1 and the plurality of second trenches TR2, and a top insulation layer 231 may be formed to cover the layer of first insulating material 501.

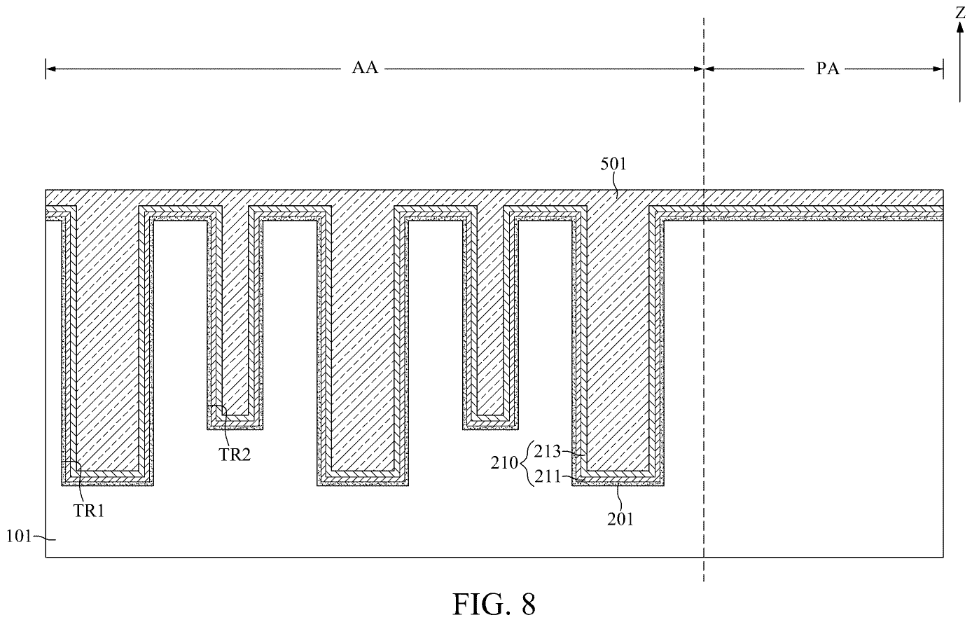

With reference to FIG. 8, a layer of first insulating material 501 may be formed on the bottom insulation layer 210 and completely fill the plurality of first trenches TR1 and the plurality of second trenches TR2. In some embodiments, the first insulating material 501 may be, for example, silicon nitride or other applicable dielectric materials. In some embodiments, the layer of first insulating material 501 may be formed by, for example, chemical vapor deposition, plasma enhanced chemical vapor deposition, or other applicable deposition processes. A planarization process, such as chemical mechanical polishing, may be performed to remove excess material and provide a substantially flat surface for subsequent processing steps.

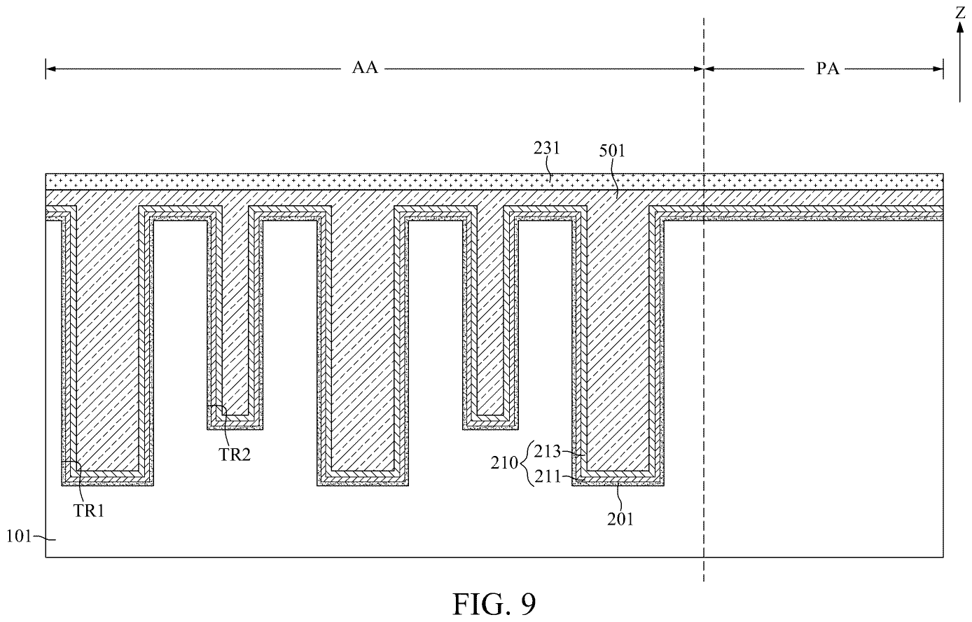

With reference to FIG. 9, the top insulation layer 231 may be formed on the layer of first insulating material 501 and completely cover the array area AA and the peripheral area PA. In some embodiments, the top insulation layer 231 may be formed of the same material as the first insulating material 501. In some embodiments, the top insulation layer 231 may be formed of, for example, silicon nitride or other applicable dielectric materials. In some embodiments, the top insulation layer 231 may be formed by, for example, chemical vapor deposition, plasma enhanced chemical vapor deposition, or other applicable deposition processes.

With reference to FIGS. 1, 10, and 11, at step S17, the top insulation layer 231, the first insulating material 501, the bottom insulation layer 210, the repair layer 201, and a portion of the substrate 101 within the peripheral area PA may be removed to turn the layer of first insulating material 501 into a filling insulation layer 220 and form a basin BN in the peripheral area PA.

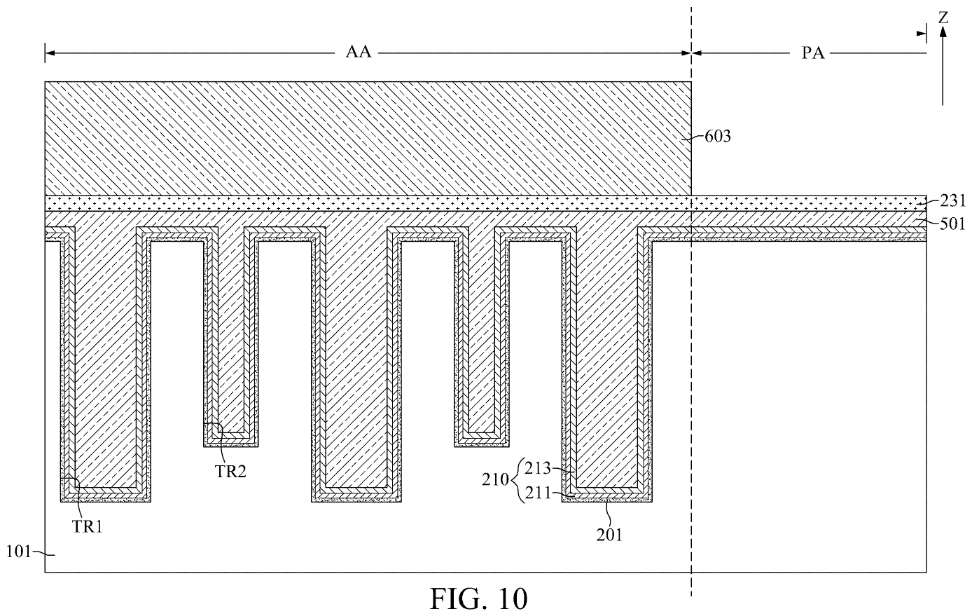

With reference to FIG. 10, a second mask layer 603 may be formed on the substrate 101 and cover the array area AA. In some embodiments, the second mask layer 603 may be a photoresist layer.

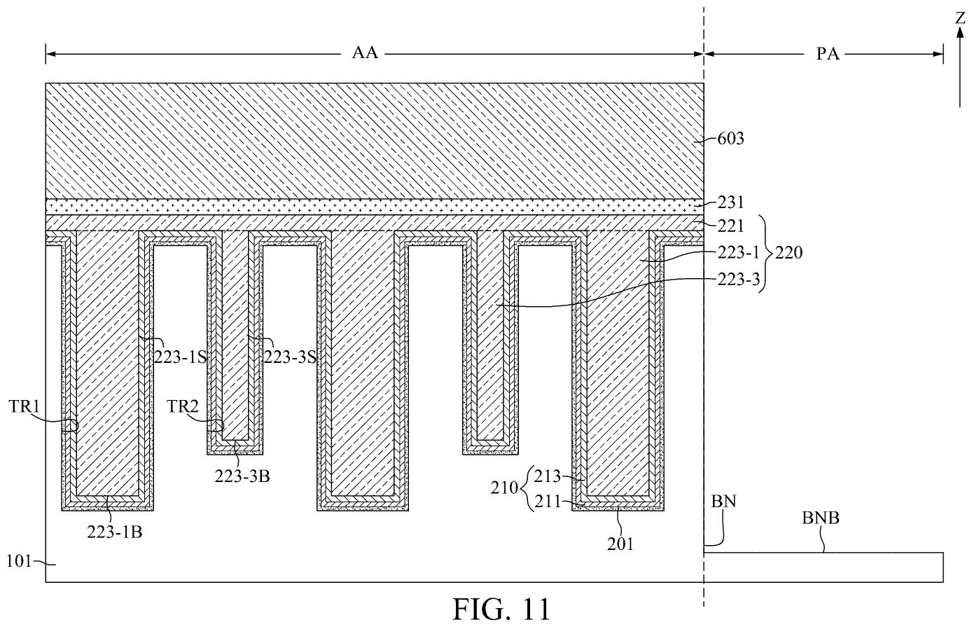

With reference to FIG. 11, an etching process may be performed using the second mask layer 603 as the mask to remove the top insulation layer 231 within the peripheral area PA, the first insulating material 501 within the peripheral area PA, the bottom insulation layer 210 within the peripheral area PA, the repair layer 201 within the peripheral area PA, and a portion of the substrate 101 within the peripheral area PA. In some embodiments, the etching process may be an anisotropic etching process such as an anisotropic dry etching process.

After the etching process, the basin BN may be formed in the peripheral area PA. The remaining first insulating material 501 within the array area AA may be referred to as the filling insulation layer 220. In some embodiments, the filling insulation layer 220 may include a flat portion 221, a plurality of first plug portions 223-1, and a plurality of second plug portions 223-3. For brevity, clarity, and convenience of description, only one first plug portion 223-1 and one second plug portion 223-3 are described. The first plug portion 223-1 may be disposed in and completely fill the plurality of first trenches TR1. The sidewalls 223-1S and the bottom surface 223-1B of the first plug portion 223-1 may be surrounded by the upper portion 213 of the bottom insulation layer 210. The second plug portion 223-3 may be disposed in and completely fill the second trench TR2. The sidewalls 223-3S and the bottom surface 223-3B of the second plug portion 223-3 may be surrounded by the upper portion 213 of the bottom insulation layer 210. The flat portion 221 may be disposed on the first plug portion 223-1 and the second plug portion 223-3.

In some embodiments, the bottom surface BNB may be lower than the bottom surface 223-1B of the first plug portion 223-1 or the bottom surface 223-3B of the second plug portion 223-3.

After the formation of the basin BN, the second mask layer 603 may be removed.

With reference to FIG. 1 and FIGS. 12 to 14, at step S19, a peripheral insulation layer 411 may be conformally formed over the top insulation layer 231 and the basin BN, and an under layer 503 may be formed to completely fill the basin BN.

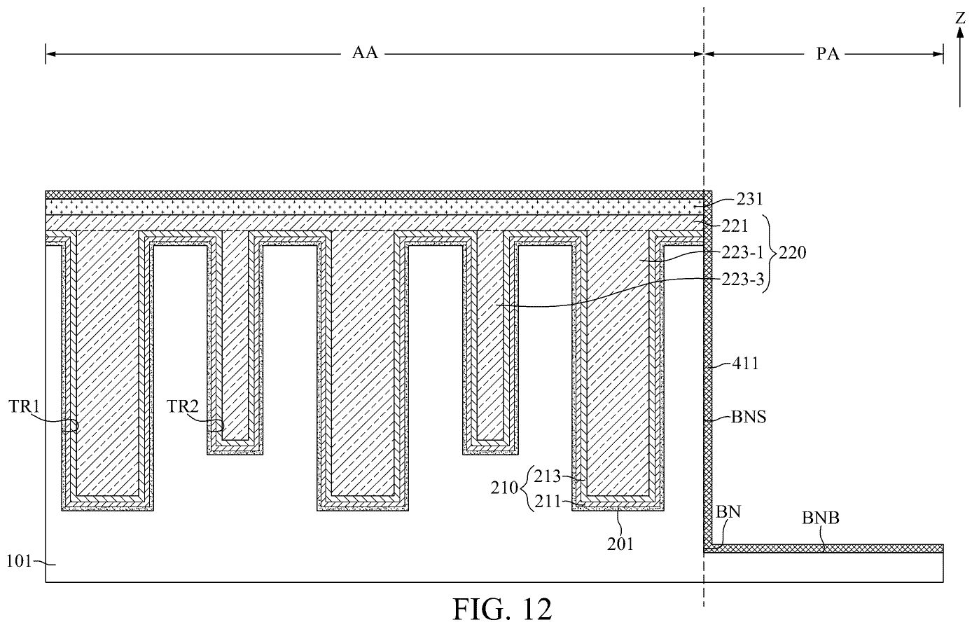

With reference to FIG. 12, the peripheral insulation layer 411 may be conformally formed to cover the top insulation layer 231 and the sidewall BNS and bottom surface BNB of the basin BN. The sidewall BNS and bottom surface BNB of the basin BN may be collectively referred to as the inner surface of the basin BN.

In some embodiments, the peripheral insulation layer 411 may be formed by a deposition process that concurrently flows tetraethoxysilane (TEOS) and ozone to the intermediate semiconductor device illustrated in FIG. 11. The substrate temperature during the deposition process may be greater than 400 °C, greater than 500 °C, or greater than 600 °C. Additives such as water (steam), hexamethyldisilazane (HMDS), and 1,1,3,3-tetramethyldisiloxane (TMDSO) may be added to ensure a more flowable or smooth deposition. Exemplary flow rates of TEOS may be greater than 0.1 gm/min (grams per minute), greater than 0.5 gm/min, greater than 1 gm/min, or greater than 3 gm/min. Exemplary flow rates of ozone may be flowing at greater than 1,000 sccm (standard cubic centimeters per minute), greater than 3,000 sccm, greater than 10,000 sccm, or greater than 30,000 sccm. The peripheral insulation layer 411 may improve adhesion and reduce incidences of delamination and cracking during and after subsequent processing. In addition, the peripheral insulation layer 411 may exhibit a smoother outer surface which may positively affect the deposition dynamics in subsequent processing.

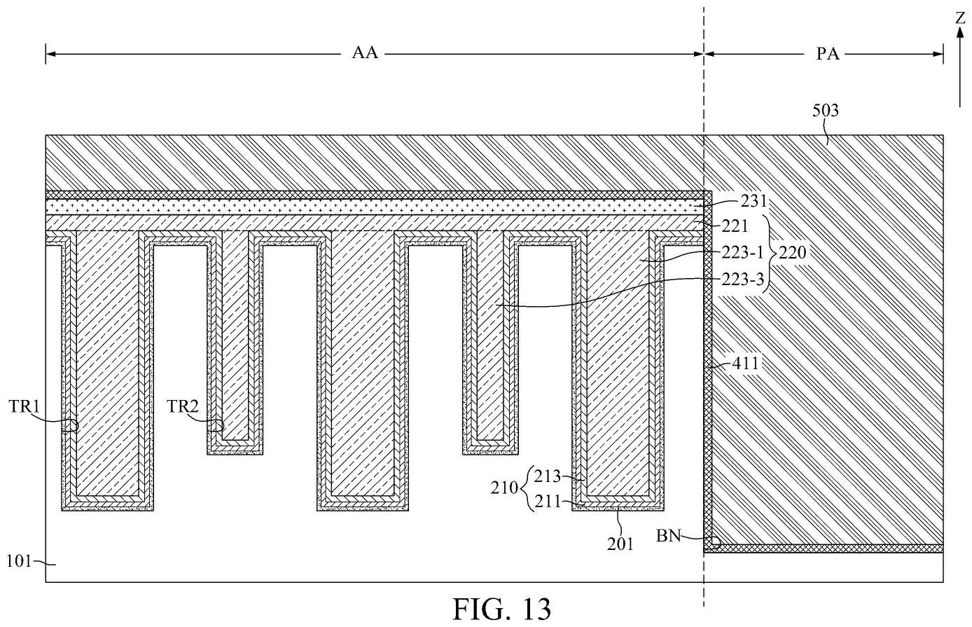

With reference to FIG. 13, the under layer 503 may be on the peripheral insulation layer 411 to completely cover the array area AA and completely fill the basin BN. In some embodiments, the under layer 503 may be a photoresist layer. In some embodiments, the under layer 503 may be formed of a material having etching selectivity to the peripheral insulation layer 411. In some embodiments, the under layer 503 may be formed of, for example, silicon nitride, silicon oxynitride, silicon nitride oxide, silicon oxygen carbide, boron nitride, silicon boron nitride, phosphorus boron nitride, boron carbon silicon nitride, metal, or other applicable materials. In some embodiments, the under layer 503 may be formed by a deposition process including, for example, chemical vapor deposition, plasma enhanced chemical vapor deposition, physical vapor deposition, evaporation, electroplating, electroless plating, spin-on coating, or other applicable deposition processes.

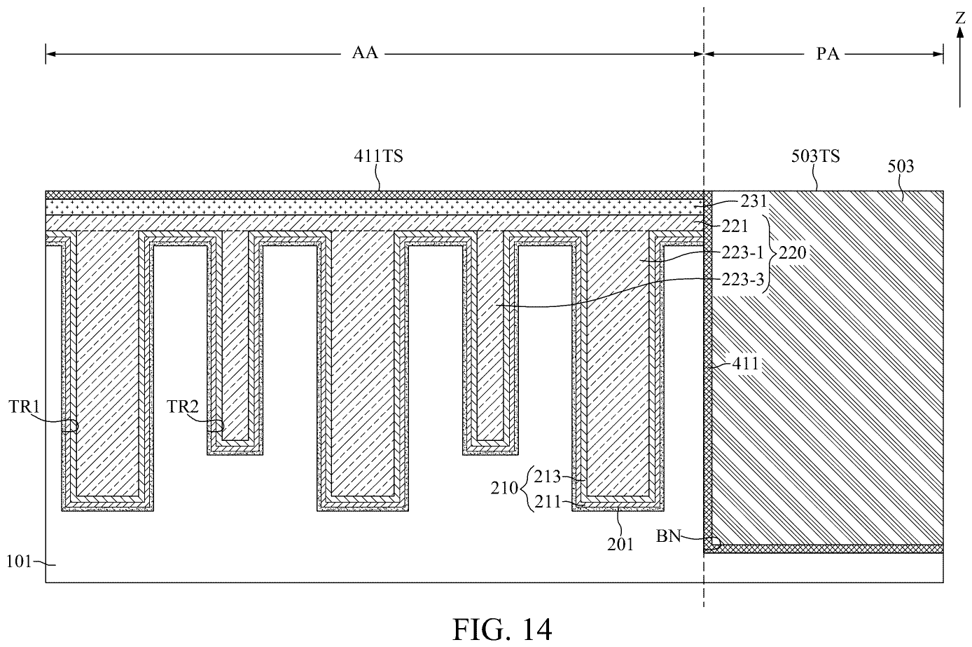

With reference to FIG. 14, a first removal process may be performed to remove a portion of the under layer 503 so as to completely expose the peripheral insulation layer 411 within the array area AA. In the current stage, the top surface 411TS of the peripheral insulation layer 411 and the top surface 503TS of the under layer 503 may be substantially coplanar. In some embodiments, the first removal process may be an etching process. In some embodiments, the first removal process may be a planarization process such as chemical mechanical polishing.

With reference to FIGS. 1, 15, and 16, at step S21, the peripheral insulation layer 411 within the array area AA may be removed to expose the top insulation layer 231, and the under layer 503 may be removed to expose the peripheral insulation layer 411 in the basin BN.

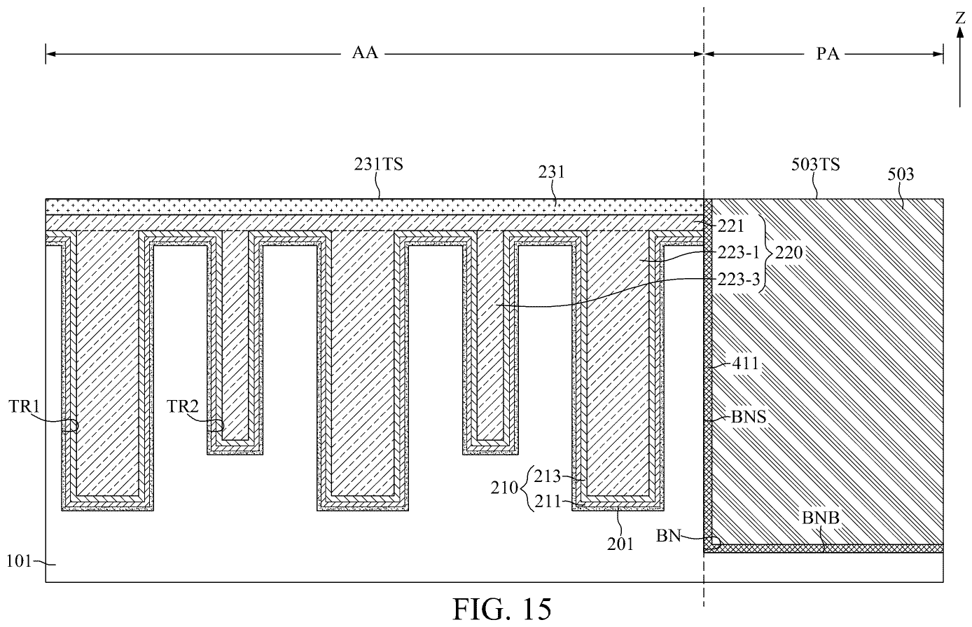

With reference to FIG. 15, a second removal process may be performed to remove the peripheral insulation layer 411 within the array area AA. The under layer 503 may be partially consumed during the second removal process. In some embodiments, the second removal process may be an etching process. For example, the second removal process may be a wet etching process. In some embodiments, the second removal process may be a planarization process such as chemical mechanical polishing. After the second removal process, the top insulation layer 231 may be completely exposed. The remaining peripheral insulation layer 411 may be only disposed within the peripheral area PA and may be conformally disposed on the sidewall BNS and the bottom surface BNB of the basin BN.

In some embodiments, in the current stage, the top surface 231TS of the top insulation layer 231 and top surface 503TS of the under layer 503 under layer 503 may be substantially coplanar.

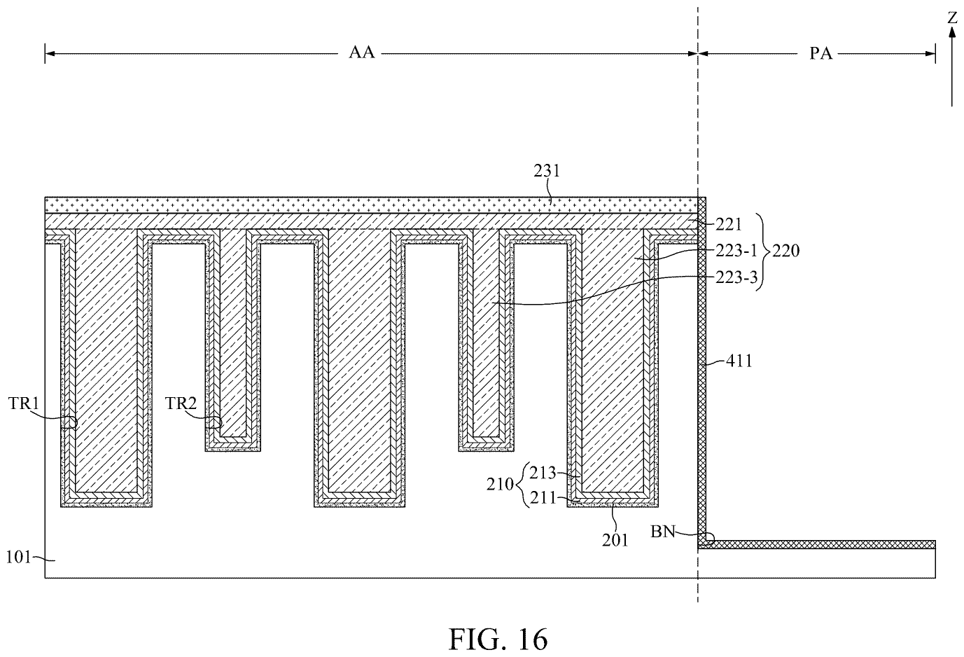

With reference to FIG. 16, a third removal process may be performed to remove the under layer 503. In some embodiments, the third removal process may be an etching process. For example, the third removal process may be a wet etching process. After the wet etching process.

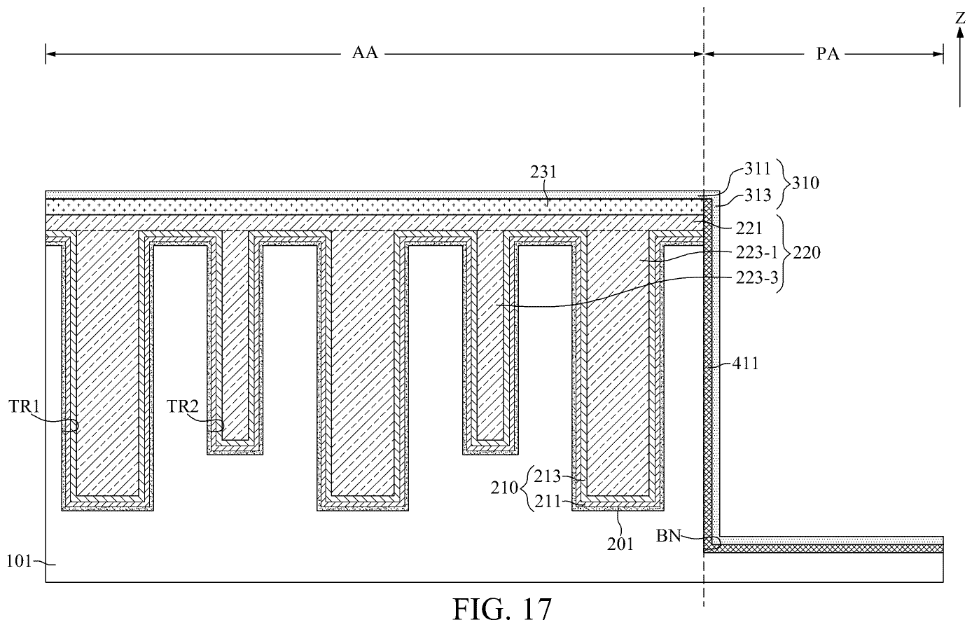

With reference to FIGS. 1 and 17, at step S23, a covering insulation liner 310 may be conformally formed to cover the top insulation layer 231 and the peripheral insulation layer 411.

With reference to FIG. 17, the covering insulation liner 310 may be conformally formed on the top insulation layer 231 and the peripheral insulation layer 411. In some embodiments, the covering insulation liner 310 may include an array portion 311 and a peripheral portion 313. The array portion 311 may be disposed on the top insulation layer 231 within the array area AA, while the peripheral portion 313 may be connected to the array portion 311 and conformally disposed on the peripheral insulation layer 411 within the basin BN. The covering insulation liner 310, which is in direct contact with the top insulation layer 231 and extends into the basin BN, may provide structural reinforcement to the trenches TR1, TR2, preventing profile deformation (particularly at the edges of the array area AA) during subsequent semiconductor processing steps. Trench profile deformation can adversely affect in-line overlay, leading to defects, degraded electrical characteristics, or reduced yield.

In some embodiments, the covering insulation liner 310 may be formed of the same material as the top insulation layer 231. In some embodiments, the covering insulation liner 310 may be formed of, for example, silicon nitride.

In some embodiments, the covering insulation liner 310 may be formed by a plasma-enhanced atomic layer deposition (PEALD) process. The process may involve exposing the intermediate semiconductor device illustrated in FIG. 16 to a silicon-containing precursor followed by sequential plasma treatments with precisely controlled gas mixtures. The process may include alternating exposures to a first plasma and a second plasma to optimize layer characteristics. The first plasma may be generated using a gas mixture of helium and nitrogen, with helium being the dominant component at a ratio ranging from 20:1 to 1000:1. The second plasma may be produced from a mixture of helium, nitrogen, and ammonia.

In some embodiments, the silicon-containing precursor can include compounds such as silane (SiH₄), disilane (Si₂H₆), chlorosilanes, or bis(diethylamino)silane (BDEAS). The first gas mixture for generating the first plasma may consist primarily of helium, accounting for 95-99.9% of the composition, with nitrogen making up the remaining 0.1-5%. The second gas mixture for generating the second plasma may include helium (75-98%), nitrogen (1-5%), and ammonia (1-20%), providing a reactive environment for layer deposition. Plasma generation may be achieved using sources such as remote plasma, inductively coupled plasma, capacitively coupled plasma, or microwave plasma, with microwave plasma being particularly advantageous due to its high density and low plasma potential. The processing chamber may be maintained at low temperatures, typically less than or equal to 600 °C, or between 300 °C and 500 °C to minimize thermal stress and damage to surrounding materials. Chamber pressures may be controlled within the range of 0.5 Torr to 5 Torr to facilitate effective precursor delivery and plasma interaction.

With reference to FIG. 1 and FIGS. 18 to 20, at step S25, a peripheral filling layer 413 may be formed to completely fill the basin BN, and a planarization process may be performed to form the semiconductor device 1A.

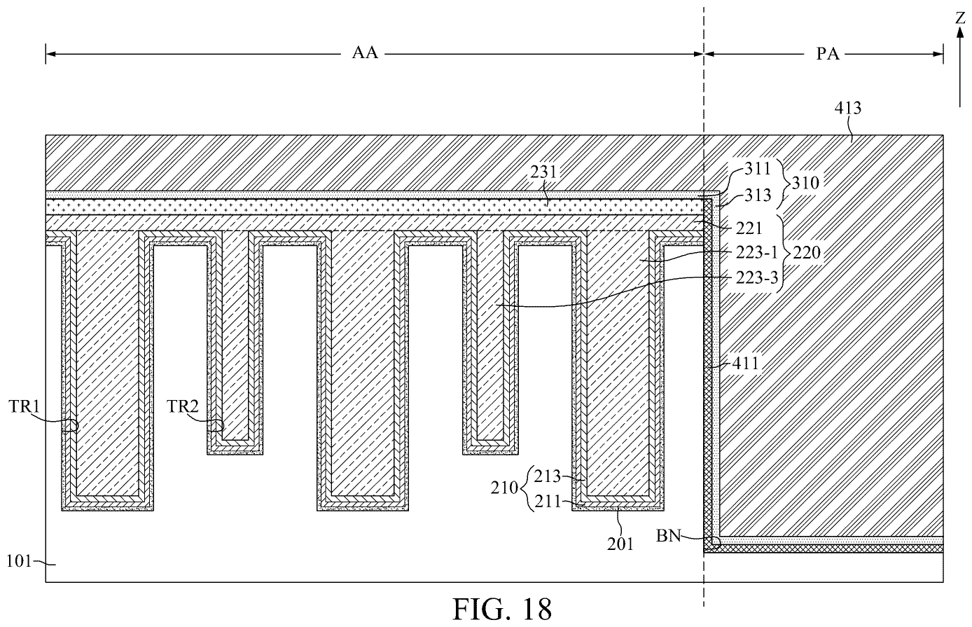

With reference to FIG. 18, the peripheral filling layer 413 may be formed on the covering insulation liner 310 and completely fill the basin BN. In some embodiments, a flowable layer (not notated for clarity) may be formed on the covering insulation liner 310. In some embodiments, the flowable layer may include compounds having unsaturated bonding such as double bonds and triple bonds. The flowable layer may be characterized as a soft jelly-like layer, a gel having liquid flow characteristics, or a liquid layer but is not limited thereto. The flowable layer may flow into and fill small substrate gaps without forming voids or weak seams. A thermal process may be subsequently performed to transform the flowable layer into the peripheral filling layer 413 by solidifying the flowable layer. The thermal process may break the unsaturated bonding into radicals, and the compounds may cross-link through the radicals. As a result, the flowable layer may be solidified. In some embodiments, the volume of the flowable layer may be reduced during the thermal process. Hence, the peripheral filling layer 413 may have greater density compared to the flowable layer.

Alternatively, in some embodiments, the flowable layer may be a flowable silicon-and-nitrogen-containing layer. The flowable silicon-and-nitrogen-containing layer may be formed by mixing a carbon-free silicon-containing precursor with a radical-nitrogen precursor. The flowable nature of the flowable silicon-and-nitrogen-containing layer may allow the flowable silicon-and-nitrogen-containing layer to flow into narrow substrate gaps or narrow trenches. The substrate temperature during the formation of the flowable silicon-and-nitrogen-containing layer may be less than 120 °C, less than 100 °C, less than 80 °C, or less than 60 °C

The carbon-free silicon-containing precursor may be, for example, a silicon-and-nitrogen precursor, a silicon-and-hydrogen precursor, or a silicon-nitrogen-and-hydrogen-containing precursor. In some embodiments, the carbon-free silicon-containing precursor may also be oxygen-free. The lack of oxygen results in a lower concentration of silanol (Si—OH) groups in the flowable silicon-and-nitrogen-containing layer formed from the carbon-free silicon-containing precursor. Excess silanol moieties in the flowable silicon-and-nitrogen-containing layer may cause increased porosity and shrinkage during subsequent processing that remove the hydroxyl (—OH) moieties from the flowable silicon-and-nitrogen-containing layer.

In some embodiments, the carbon-free silicon-containing precursor may include silyl-amines such as H₂N(SiH₃), HN(SiH₃)₂, and N(SiH₃)₃. The flow rates of silyl-amines may be greater than or about 200 sccm, greater than or about 300 sccm, or greater than or about 500 sccm. These silyl-amines may be mixed with additional gases that may act as carrier gases, reactive gases, or both. Examples of these additional gases may include H₂, N₂, NH₃, He, and Ar.

In some embodiments, the carbon-free silicon-containing precursor may include silane either alone or mixed with other silicon (e.g., N(SiH₃)₃), hydrogen (e.g., H₂), and/or nitrogen (e.g., N₂, NH₃) containing gases.

In some embodiments, the carbon-free silicon-containing precursor may include disilane, trisilane, even higher-order silanes, and chlorinated silanes, alone or in combination with silyl-amines.

The radical-nitrogen precursor may be generated by delivering ammonia to a plasma region. The radical-nitrogen precursor may be subsequently delivered to mix with the carbon-free silicon-containing precursor. The flow rate of delivering ammonia to the plasma region may be greater than or about 300 sccm, greater than or about 500 sccm, or greater than or about 700 sccm. In some embodiments, gases such as nitrogen and hydrogen may be employed to adjust the nitrogen: hydrogen atomic flow ratio. In some embodiments, gases such as helium or argon may be employed as carrier gas for delivering ammonia to the plasma region.

In some embodiments, the radical-nitrogen precursor may be produced without using ammonia. Gases include one or more of hydrogen, nitrogen and hydrazine may be delivered to the plasma region to generate the radical-nitrogen precursor.

Subsequently, a cure process and an anneal process may be sequentially applied to the flowable silicon-and-nitrogen containing layer (i.e., the flowable layer) in an oxygen-containing atmosphere to convert the flowable silicon-and-nitrogen containing layer into the peripheral filling layer 413 formed of silicon oxide. In some embodiments, the substrate temperature of the cure process may be below or about 400 °C. For example, the substrate temperature of the cure process may be between about 100 °C and about 200 °C. In some embodiments, the substrate temperature of the anneal process may be between about 500 °C and about 1100 °C. In s ome embodiments, the oxygen-containing atmosphere may include one or more oxygen-containing gases such as molecular oxygen, ozone, water vapor, hydrogen peroxide, and nitrogen-oxides (e.g., nitric oxide, nitrous oxide, etc.).

Alternatively, in some embodiments, the flowable layer may be formed by reacting vapor phase precursors with co-reactants. The flowable layer may have flow characteristics that can provide consistent fill of substrate gaps. Subsequently, a post-deposition treatment may be performed, and the flowable layer may be physically densified and/or chemically converted to reduce its flowability. After the post-deposition treatment, the flowable layer may be turned into the peripheral filling layer 413. In some embodiments, the densified flowable layer may be considered to be solidified. In some embodiments, physically densifying the flowable layer may involve shrinking the flowable layer. In some embodiments, the post-deposition treatment may involve substituting chemicals in the flowable layer, which may result in denser, higher volume peripheral filling layer 413.

In some embodiments, the flowable layer may be flowable silicon oxide, silicon nitride, or silicon oxynitride. In some embodiments, the flowable layer may be silicon carbide or silicon oxycarbide. In some embodiments, chamber pressure for formation of the flowable layer may be between about 1 and 200 Torr, between 10 and 75 Torr, or about 10 Torr. In some embodiments, substrate temperature for formation of the flowable layer may be between about −20 °C and about 100 °C, between about −20 °C and 30 °C, or between about −10 °C and about 10 °C.

In some embodiments, the vapor phase precursors may include silicon containing precursors or carbon containing precursors. The co-reactants may include oxidants, catalyst, surfactants, or inert carrier gases.

The silicon containing precursors may include, but are not limited to, silane, disilane, trisilane, hexasilane, cyclohexasilane, alkoxysilanes, aminosilanes, alkylsilanes, tetraisocyanatesilane (TICS), hydrogen silsesquioxane, T8-hydridospherosiloxane, or 1,2-dimethoxy-1,1,2,2-tetramethyldisilane.

The alkoxysilanes may include tetraoxymethylcyclotetrasiloxane (TOMCTS), octamethylcyclotetrasiloxane (OMCTS), tetraethoxysilane (TEOS), triethoxysilane (TES), trimethoxysilane (TriMOS), methyltriethoxyorthosilicate (MTEOS), tetramethylorthosilicate (TMOS), methyltrimethoxysilane (MTMOS), dimethyldimethoxysilane (DMDMOS), diethoxysilane (DES), dimethoxysilane (DMOS), triphenylethoxysilane, 1-(triethoxysilyl)-2-(diethoxymethylsilyl)ethane, tri-t-butoxylsilanol, hexamethoxydisilane (HMODS), hexaethoxydisilane (HEODS), or tert-butoxydisilane. The aminosilanes may include bis-tert-butylamino silane (BTBAS) or tris(dimethylamino)silane.

The carbon containing precursors may include, but are not limited to, trimethylsilane (3MS), tetramethylsilane (4MS), diethoxymethylsilane (DEMS), dimethyldimethoxysilane, methyl-triethoxysilane (MTES), methyl-trimethoxysilane, methyl-diethoxysilane, methyl-dimethoxysilane, trimethoxymethylsilane, dimethoxymethylsilane, or bis(trimethylsilyl)carbodiimide.

The oxidants may include, but are not limited to, ozone, hydrogen peroxide, oxygen, water, alcohols, nitric oxide, nitrous dioxide, nitrous oxide, carbon monoxide, or carbon dioxide. The alcohols may include, for example, methanol, ethanol, or isopropanol.

The catalyst may include, but are not limited to, proton donor catalyst, halogen-containing compounds, mineral acids, bases, chloro-diethoxysilane, methanesulfonic acid, trifluoromethanesulfonic acid, chloro-dimethoxysilane, pyridine, acetyl chloride, chloroacetic acid, dichloroacetic acid, trichloroacetic acid, oxalic acid, benzoic acid, or triethylamine. The proton donor catalyst may include nitric acid, hydrofluoric acid, phosphoric acid, sulphuric acid, hydrochloric acid, bromic acid, carboxylic acid derivatives, ammonia, ammonium hydroxide, hydrazine, or hydroxylamine. The halogen-containing compounds may include dichlorosilane, trichlorosilane, methylchlorosilane, chlorotriethoxysilane, chlorotrimethoxysilane, chloromethyldiethoxysilane, chloromethyldimethoxysilane, vinyltrichlorosilane, diethoxydichlorosilane, or hexachlorodisiloxane. The mineral acids may include formic acid or acetic acid. The bases may include phosphine.

The surfactants may include solvents, alcohols, ethylene glycol, or polyethylene glycol. The surfactants may be used to relieve surface tension and increase wetting of reactants on the substrate surface. The surfactants may also increase the miscibility of the vapor phase precursors with the other reactants.

The solvents may be non-polar or polar and protic or aprotic. The solvents may be matched to the choice of vapor phase precursors to improve the miscibility in the oxidants. Non-polar solvents may include alkanes and alkenes; polar aprotic solvents may include acetones and acetates; and polar protic solvents may include alcohols and carboxylic compounds.

Examples of solvents include, but not limited to, methanol, ethanol, isopropanol, acetone, diethylether, acetonitrile, dimethylformamide, dimethyl sulfoxide, tetrahydrofuran, dichloromethane, hexane, benzene, toluene, isoheptane and diethylether. In some embodiments, the solvents may be introduced prior to the other reactants.

The inert carrier gases may include nitrogen, helium, or argon.

The post-deposition treatment may cross-link and remove terminal groups such as —OH and —H groups in the flowable layer, therefore increase the density and hardness of the peripheral filling layer 413. The post-deposition treatment may be thermal curing, exposure to a downstream or direct plasma, exposure to ultraviolet or microwave radiation, or exposure to another energy source.

While using thermal curing as the means of the post-deposition treatment, the temperature of thermal curing may be between about 200 °C and 600 °C. The post-deposition treatment may be performed in an inert environment, an oxidizing environment, a nitridizing environment, or a mix of oxidizing and nitridizing environment. The inert environment may include argon or helium. The oxidizing environment may include oxygen, ozone, water, hydrogen peroxide, nitrous oxide, nitric oxide, nitrogen dioxide, carbon monoxide, carbon dioxide. The nitridizing environment may include nitrogen, ammonia, nitrous oxide, nitric oxide, and nitrogen dioxide. The pressure of thermal curing may be between about 0.1 Torr and about 10 Torr.

While using the exposure to a downstream or direct plasma as the means of the post-deposition treatment, the plasma may be an inert plasma or a reactive plasma. The inert plasma may be helium and argon plasma. The reactive plasma may be oxidizing plasma including oxygen and steam, or hydrogen-containing plasma including hydrogen and a diluent such as inert gas. In some embodiments, the temperature during plasma exposure may be about 25 °C or higher. In some embodiments, the temperature during plasma exposure may be between about −15 °C and about 25 °C.

In some embodiments, an additional plasma treatment may be performed between the formation of the flowable layer and the post-deposition treatment. The additional plasma treatment may be effective to remove porosity and densify the flowable layer in the substrate gaps if the flowable layer is still in a flowable state. The additional plasma treatment may use a plasma having a primary component of hydrogen, helium, nitrogen, or argon.

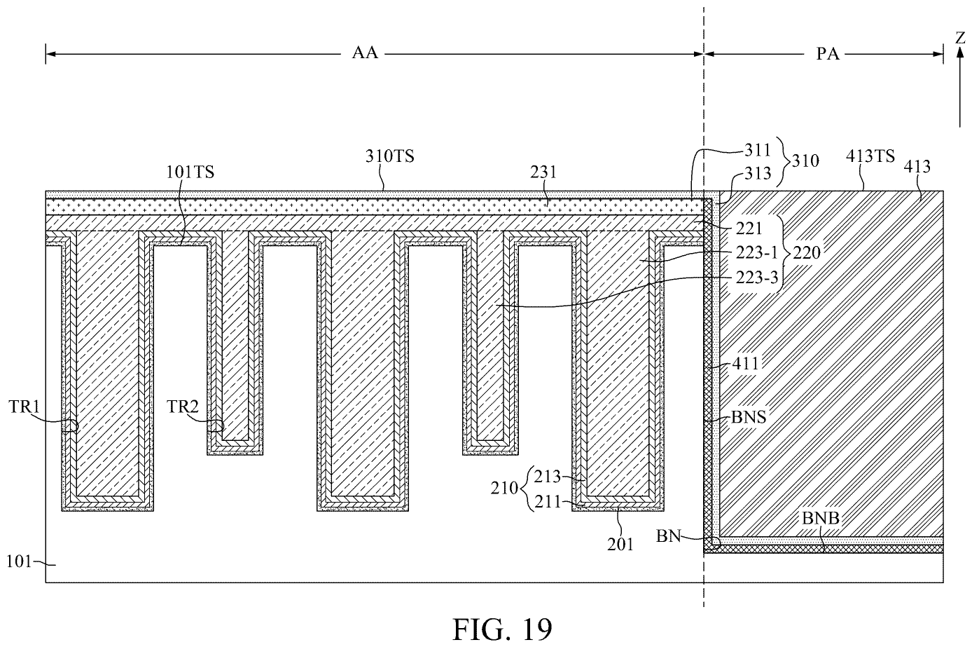

With reference to FIG. 19, a planarization process, such as chemical mechanical polishing, may be performed until the top surface of the covering insulation liner 310 is exposed to remove excess material and provide a substantially flat surface for subsequent processing steps. In the current stage, the top surface 310TS of the covering insulation liner 310 and the top surface 413TS of the peripheral filling layer 413 may be substantially coplanar.

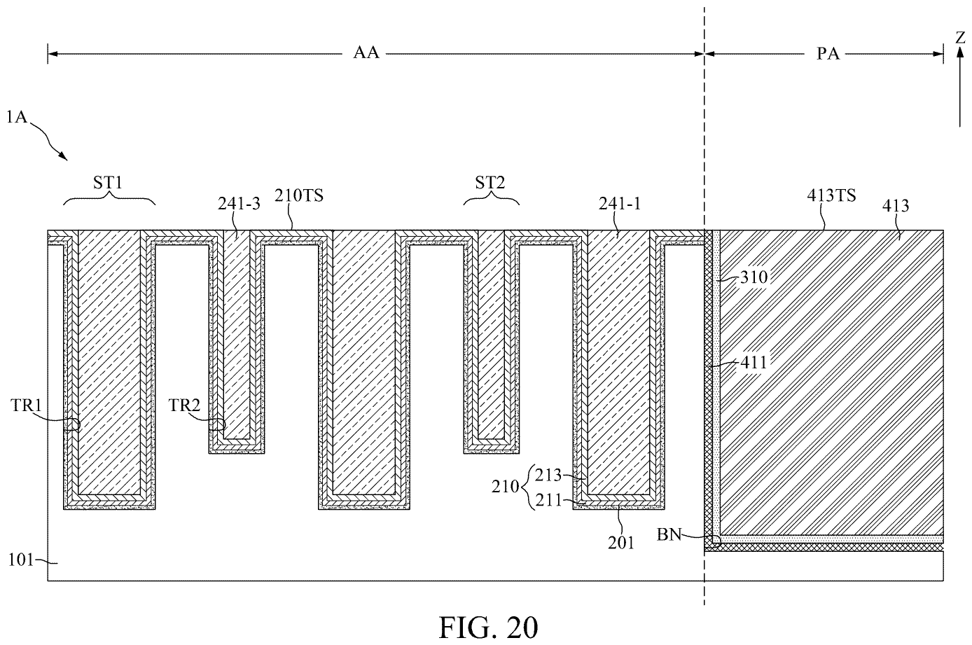

With reference to FIG. 20, a planarization process, such as chemical mechanical polishing, may be performed until the top surface 210TS is exposed to remove excess material and provide a substantially flat surface for subsequent processing steps. After the planarization process, the flat portion 221 of the filling insulation layer 220 may be removed. The remaining filling insulation layer 220 in the first trenches TR1 may be referred to as the plurality of first filling insulation layers 241-1. The remaining filling insulation layer 220 in the second trenches TR2 may be referred to as the plurality of second filling insulation layers 241-3.

The repair layer 201, the bottom insulation layer 210, and the plurality of first filling insulation layers 241-1 may be referred to as the plurality of first isolation structures ST1. The repair layer 201, the bottom insulation layer 210, and the plurality of second filling insulation layers 241-3 may be referred to as the plurality of second isolation structures ST2.

Due to the significant pattern density differences between the array area AA and the peripheral area PA, the element profiles (e.g., trench profiles) near the edge of the array area AA may be susceptible to deformation. In the present disclosure, the covering insulation liner 310 directly covers the top insulation layer 231 while conformally extending to the inner surface of the basin BN within the peripheral area PA, providing structural reinforcement to the element profiles within the array area AA. As a result, defects in the semiconductor device 1A may be reduced, while in-line overlay accuracy and overall yield may be improved.

One aspect of the present disclosure provides a semiconductor device including a substrate including an array area and a peripheral area adjacent to the array area; a first trench inwardly positioned in the array area; a basin inwardly positioned in the peripheral area; a filling insulation layer completely filling the first trench and covering a top surface of the substrate within the array area; a top insulation layer positioned on the filling insulation layer and within the array area; and a covering insulation liner conformally and completely covering the top insulation layer and an inner surface of the basin. The covering insulation liner and the top insulation layer contact each other directly.

Another aspect of the present disclosure provides a semiconductor device including a substrate including an array area and a peripheral area adjacent to the array area; a filling insulation layer including a first plug portion positioned in the array area of the substrate, and a flat portion positioned on the first plug portion and covering a top surface of the substrate within the array area; a top insulation layer positioned on the flat portion of the filling insulation layer and within the array area; a peripheral filling layer positioned in the peripheral area of the substrate and adjacent to the array area of the substrate; and a covering insulation liner including an array portion conformally covering the top insulation layer, and a peripheral portion connecting to the array portion and positioned between the peripheral filling layer and the substrate.

Another aspect of the present disclosure provides a method for fabricating a semiconductor device including providing a substrate including an array area and a peripheral area adjacent to the array area, and forming a plurality of first trenches in the array area; forming a layer of first insulating material filling the plurality of first trenches and covering the array area and the peripheral area, and forming a top insulation layer covering the layer of first insulating material; removing the top insulation layer within the peripheral area, the first insulating material within the peripheral area, and a portion of the substrate within the peripheral area to turn the layer of first insulating material into a filling insulation layer in the array area and form a basin in the peripheral area; conformally forming a peripheral insulation layer on the top insulation layer and within the basin; forming an under layer to completely fill the basin; removing the peripheral insulation layer within the array area to expose the top insulation layer; removing the under layer to expose the peripheral insulation layer within the peripheral area; and conformally forming a covering insulation liner covering the top insulation layer and the peripheral insulation layer.

Due to the design of the semiconductor device of the present disclosure, the covering insulation liner 310, which is in direct contact with the top insulation layer 231 and extends to the basin BN of the peripheral area PA, may provide structural reinforcement to the trenches TR1, TR2, preventing profile deformation (particularly at the edges of the array area AA) during subsequent semiconductor processing steps. As a result, the defect of the semiconductor device 1A may be reduced, and the in-line overlay, electrical characteristics, and yield of the semiconductor device 1A may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate comprising an array area and a peripheral area adjacent to the array area;
a first trench inwardly positioned in the array area;
a basin inwardly positioned in the peripheral area;
a filling insulation layer completely filling the first trench and covering a top surface of the substrate within the array area;
a top insulation layer positioned on the filling insulation layer and within the array area; and
a covering insulation liner conformally and completely covering the top insulation layer and an inner surface of the basin;
wherein the covering insulation liner and the top insulation layer contact each other directly.

2. The semiconductor device of claim 1, further comprising a peripheral insulation layer conformally positioned between the covering insulation liner and the inner surface of the basin.

3. The semiconductor device of claim 1, further comprising a bottom insulation layer conformally positioned along the first trench and positioned between the filling insulation layer and the substrate within the array area.

4. The semiconductor device of claim 3, further comprising a repair layer conformally positioned between the filling insulation layer and the substrate within the array area.

5. The semiconductor device of claim 3, wherein the bottom insulation layer comprises:
a lower portion conformally positioned along the first trench and positioned between the filling insulation layer and the substrate within the array area; and
an upper portion conformally positioned between the lower portion and the filling insulation layer.

6. The semiconductor device of claim 5, wherein a thickness of the upper portion is between about 5 nm and about 15 nm.

7. The semiconductor device of claim 5, wherein a thickness of the lower portion is between about 1 nm.

8. The semiconductor device of claim 5, wherein the lower portion and the upper portion comprise silicon oxide.

9. The semiconductor device of claim 1, wherein the covering insulation liner comprises silicon nitride.

10. The semiconductor device of claim 1, wherein the top insulation layer comprises silicon nitride.

11. The semiconductor device of claim 2, wherein the peripheral insulation layer comprises silicon oxide.

12. The semiconductor device of claim 8, wherein an atomic composition of the upper portion comprises silicon, oxygen, chlorine, and hydrogen.

13. The semiconductor device of claim 8, wherein an atomic composition of the lower portion comprises silicon and oxygen.
